(19) United States
(12) Patent Application Publication
(10) Pub. No.: US 2011/0084367 A1
(43) Pub. Date: Apr. 14, 2011

(54) EPITAXIAL WAFER AND METHOD OF PRODUCING THE SAME

(75) Inventors: Hideki NISHIHATA, Tokyo (JP); Yoshihisa NONOGAKI, Tokyo (JP); Akihiko ENDO, Tokyo (JP)

(73) Assignee: SUMCO CORPORATION, Tokyo (JP)

(21) Appl. No.: 12/897,907

(22) Filed: Oct. 5, 2010

(30) Foreign Application Priority Data
Oct. 9, 2009 (JP) 2009-235295

(51) Int. Cl. H01L 23/00; H01L 21/762

(52) U.S. Cl. 257/632; 438/787; 257/E23.002; 257/E21.561

(57) ABSTRACT

A method of producing an epitaxial wafer, comprising: implanting oxygen ions from a surface of a silicon wafer, thereby forming an ion implanted layer in a surface layer of the silicon wafer; after forming the ion implanted layer, implanting boron ions from the surface of the silicon wafer to the whole area in the ion implanted layer; performing heat treatment of the silicon wafer after implanting boron ions, thereby forming a thinning-stopper layer including a mixture of silicon particles, silicon oxides, and boron, and forming an active layer in the silicon wafer on the surface side of the thinning-stopper layer; and forming an epitaxial layer on the surface of the silicon wafer after the heat treatment.

### BACKGROUND OF THE INVENTION

1. Field of the Invention

The present invention relates to an epitaxial wafer and method of producing the same, specifically relates to an epitaxial wafer which can be thinned with high accuracy without using a silicon wafer of a perfect SOI structure, and relates to a method of producing the same.

Priority is claimed on Japanese Patent Application 2009-235295 filed on Oct. 9, 2009, the content of which is incorporated herein by reference.

2. Background of the Invention

In an SOI (Silicon On Insulator) wafer generally known, a buried oxide film is formed in the surface vicinity of a silicon wafer, thereby forming an active layer on the surface side of the buried oxide film. An SIMOX (Separation by IMplanted OXygen) wafer has been developed as a type of the SOI wafer. In the SMOX wafer, an ion implanted layer is formed in the surface layer of the silicon wafer by implanting oxygen ions from the surface of the silicon wafer, and subsequently performing heat treatment of the wafer thereby converting the ion implanted layer to the buried oxide film (buried silicon oxide film).

The SIMOX wafer is frequently processed to an epitaxial SIMOX wafer by forming an epitaxial layer on the surface of the wafer and is used as a wafer for CIS (CMOS Image Sensor), a kind of solid-state imaging device (for example, Japanese Unexamined Patent Application, First Publication, No. 2005-333052). An image sensor is a device that captures image information utilizing photosensitive reaction property of a semiconductor. In a CIS, imaging light from an object of imaging placed outside the device is absorbed and photon charges are accumulated by a photo-diode as a light-receiving element.

In a device formation process, a solid-state imaging device is formed on the surface of the epitaxial film. Subsequently, a support substrate made of silicon is bonded to the surface of the epitaxial film, thereby forming a bonded wafer. Next, backside of the silicon wafer constituting the bonded wafer is thinned by grinding and polishing or by etching. Thus, it is possible to obtain a back-illuminated type solid-state imaging device in which solid-state imaging elements are buried in backside of the epitaxial film (interstices between the bonded wafer).

At that time, oxygen ion implantation is performed by conditions including a temperature of heating the substrate at 200° C. to 600° C., ion implantation energy of 20 to 220 keV, a dose of ion implantation of 1.5×10¹⁷ to 2.0×10¹⁸ atoms/cm². The buried oxide film is used as a polish-stopping member or an etch-stopping member when the thinning of the wafer proceeds from the silicon wafer to the buried oxide. Here the etch-stopping is performed utilizing material properties such as change of polishing resistance of the wafer due to the difference in hardness between the silicon oxide and silicon or the change of the etching rate due to the difference in the etching rate between the silicon oxide and silicon in the etching liquid.

As described above,when a SIMOX wafer is applied as a substrate constituting a main body of a solid-state imaging device, it is possible to perform polish-stopping and etch-stopping of the silicon wafer easily and precisely in the process of thinning a silicon wafer of a bonded wafer from its backside. Further, since the silicon wafer is subjected to a high temperature heat treatment at a temperature of 1300° C. or more for a duration of 4 hours or more, it is possible to erase oxygen ion implantation defects (e.g., oxygen precipitates) in the active layer, which may otherwise constitute nuclei of epitaxial growth defects.

However, when a SIMOX wafer is applied, perfectly dense buried oxide layer (perfect buried oxide layer) composed of continuous SiO₂ is formed in the surface layer of the substrate by heat treatment of the silicon wafer at a temperature of 1300° C. or more for a duration exceeding 4 hours. Therefore, a process of high temperature annealing of the silicon wafer for a long time has been required, resulting in increasing production cost of epitaxial SIMOX wafers.

Recently, solutions for suppressing metal-contamination of an epitaxial film in which the solid-imaging device is formed is required in the wafer for CIS for preventing reduction of yield of solid imaging device.

An object of the present invention is to provide an epitaxial wafer and a method of producing the same by which frequency of generation of growth defects of an epitaxial film caused by the oxygen ion implantation defects in the surface layer is reduced, polish-stopping and etch-stopping of a silicon wafer is performed precisely utilizing the thinning-stopper layer in the process of thinning the wafer, and metallic impurities in the epitaxial film and metallic impurities in the active layer are trapped.

### SUMMARY OF THE INVENTION

A first aspect of the present invention is a method of producing an epitaxial wafer, including: forming an ion implanted layer in a surface layer (surface-vicinity layer, surface vicinity portion) of a silicon wafer by implanting oxygen ions from a surface of the silicon wafer; implanting boron ions to an entire area in the ion implanted layer from the surface of the silicon wafer after forming the ion implanted layer; performing heat treatment of the ion implanted layer after implanting the boron ions, thereby forming a thinning-stopper layer in which silicon particles, silicon oxides, and boron are mixed while forming an active layer on a surface-side of the thinning-stopper layer in the silicon wafer; and forming an epitaxial film on the surface of the silicon wafer after the heat treatment.

As a result of extensive investigation, the inventors found that when a thinning-stopper layer (imperfect buried oxide layer) mixing silicon particles, silicon oxides, and boron (boron ions and/or boron atoms) was formed in the surface layer of a silicon wafer, all of the above described problems were solved in an epitaxial wafer having such a silicon wafer formed as an alternative to conventional epitaxial SIMOX wafer having a perfectly dense buried oxide film of continuous SiO₂ in the whole area of the wafer. Based on this finding, the inventors completed the invention.

In the above-described method, in the ion implantation, dose of oxygen ions implanted to the surface layer of the silicon wafer is controlled to be smaller than the dose of implanted oxygen ions in the conventional epitaxial SIMOX wafer. In the heat treatment (annealing) of the ion implanted layer after the ion implantation, heat treatment of the silicon wafer is performed at a lower temperature for a shorter duration compared to the high temperature annealing in the formation of an epitaxial SIMOX wafer. Thus, thinning-stopper layer is formed in the surface layer of the silicon wafer.

Heat treatment in the formation of the thinning-stopper layer is performed at lower temperature for a shorter duration compared to temperature and duration of heat treatment to form a buried oxide film in a SIMOX wafer. In general, ion implantation defects formed in the surface layer of the wafer at the time of oxygen ion implantation do not disappear in such heat treatment conditions. However, in the above-described method, oxygen precipitates as oxygen ion implantation defects constitute a partial portion of a thinning-stopper layer while being trapped by boron existing in the whole area of the thinning-stopper layer. Thus, it is possible to erase the oxygen ion implantation defects in the active layer even by low-temperature heat treatment conditions. As a result, it is possible to reduce the frequency of generation of growth defects (epitaxial defects) of an epitaxial film due to the presence of oxygen ion implantation defects during the formation of an epitaxial layer.

Further, the boron function as gettering sites to getter metallic impurities in the epitaxial film and the active layer. Therefore, metallic impurities are captured by boron at the time of forming an epitaxial film. As a result, it is possible to obtain an epitaxial film of high quality.

Further, the thinning-stopper layer is an imperfect buried oxide film in which silicon particles, silicon oxides, and boron are mixed. Therefore, like in a case of conventional epitaxial SIMOX wafer, it is possible to perform polish-stopping and/or etch-stopping of the silicon wafer precisely using the thinning-stopper layer at the time of thinning the silicon wafer.

In the above-described method, surface layer (surface-vicinity layer) of the silicon wafer may present in the range of 0.05 to 0.5 μm in a depth from the surface of the silicon wafer. The implantation of boron ions in the whole area of the ion implanted layer denotes ion implantation of boron ions to all of the area where the oxygen ions have been implanted in the wafer.

A second aspect of the present invention is a method of producing an epitaxial wafer, wherein a dose of the oxygen ion implantation is 1.0×10¹⁴ to 2.0×10¹⁷ atoms/cm². The dose of the oxygen ion implantation may be 1.0×10¹⁵ to 1.0×10¹⁷ atoms/cm².

A third aspect of the present invention is a method of producing an epitaxial wafer according to the above-described first aspect or second aspect, wherein a dose of the boron ion implantation may be 1.0×10¹⁵ to 1.0×10¹⁶ atoms/cm². The dose of boron ion implantation may be 1.0×10¹⁵ to 5.0×10¹⁵ atoms/cm².

A fourth aspect of the present invention is a method of producing an epitaxial wafer according to any one of the above-described first aspect to third aspect, wherein a peak depth of the boron ion implantation is within a range of ±500 Å of a peak depth of oxygen ion implantation. Here, the peak depth denotes a depth where the implanted ions have the largest concentration.

The silicon wafer used in the above-described method may be a single crystalline silicon wafer. A surface of the silicon wafer may be mirror-polished. A diameter of the silicon wafer is not limited. For example, it is possible to use a silicon wafer having a diameter of 200 mm, 300 mm, or 450 mm.

Preferably, a depth of oxygen ion implantation in the surface layer of the silicon wafer is in the range of 0.05 to 0.5 μm from a surface of the silicon wafer.

The thinning-stopper layer is an imperfect silicon oxide film (imperfect buried oxide film) buried in a silicon wafer, where silicon oxide and silicon particles are mixed in a predetermined proportion in the layer. The silicon particles originate from silicon in the silicon wafer which is made particles (pulverized) by the oxygen ion implantation. The silicon oxide may contain SiO₂. Preferably, a thickness of the thinning-stopper layer is 0.05 to 0.5 μm.

The oxygen ion implantation may be performed by an ion implantation method used in a SIMOX process. For example, it is possible to use a low-energy method (100 keV or less), la ow-dose method, a modified low-dose method or the like.

In any of the method, preferable dose of oxygen ion implantation is more than ⅛ and not more than ½ of a dose of oxygen implantation in the SIMOX process (for example, 1.5 ×10¹⁷ to 2 ×10¹⁸ atoms/cm²) using the corresponding method.

The wafer may be heated at the time of oxygen ion implantation. The heating temperature may be 200° C. to 600° C.

The energy of oxygen ion implantation may be 20 to 220 KeV.

The oxygen ion implantation may be performed in a single step, or may be performed by plural steps. When the oxygen ion implantation is performed by plural steps, it is possible to implant oxygen ions with different implantation energies in different steps.

Implantation energies of boron may be controlled such that a peak of the boron concentration is formed in a depth in a range of ±500 Å of a peak depth of oxygen ion implantation. That is, when D denotes a peak depth of the oxygen ion implantation, a peak depth of the boron ion implantation may be in the range of D-500 Å to D+500 Å.

The boron ion implantation may be performed in a single step, or may be performed in plural steps. When the boron ion implantation is performed in plural steps, it is possible to implant boron ions with different implantation energies in different steps.

Preferably, heating temperature of the wafer in the heat treatment to form the thinning-stopper layer is controlled to 900° C. to 1200° C.

Duration of the heat treatment is preferably 0.5 to 4 hours.

The heat treatment may be performed in an inert gas atmosphere.

In the heat treatment, a gettering layer containing boron may be formed between the active layer and the thinning-stopper layer.

The heat treatment may be a heat treatment of a silicon wafer during formation of an epitaxial layer, or heat treatment in a device process.

The epitaxial film formed by the epitaxial growth may be a single crystalline silicon film.

Preferably, a thickness of the epitaxial film is 1 to 20 μm.

Preferably, the epitaxial growth temperature (heating temperature of the wafer) is controlled to be 1000 to 1200° C.

Formation of the epitaxial film may be performed by any method selected from vapor-phase epitaxial method (VPE), liquid-phase epitaxial method (LPE), and solid-phase epitaxial method (SPE). For example, it is possible to use a chemical vapor deposition (CVD) method.

When CVD method is used, it is possible to deposit a silicon at a temperature of 1000° C. or more (for example, 1000 to 1200° C.) while introducing silicon-containing source gas and carrier gas into the chamber. The carrier gas may be hydrogen gas. The source gas may be any one selected from SiH₄, SiH₂Cl₂, SiHCl₃, and SiCl₄.

For example, the epitaxial growth may be performed using a high-frequency induction heating type epitaxial growth furnace, or a lamp heating type epitaxial growth furnace.

A fifth aspect of the present invention is a method of producing a bonded wafer, including: forming an epitaxial wafer having an epitaxial film formed on a first silicon wafer in accordance with any of the above-described method; bonding a second semiconductor substrate on a front surface of the epitaxial wafer; and thinning the first silicon wafer from a back surface of the first silicon wafer.

The above-described method may include forming device in an epitaxial layer before the binding.

For example, thinning of the wafer may be performed by grinding, polishing, and/or etching. During the thinning, the silicon wafer after grinding may be subjected to polishing or etching. For example, it is possible to grind a silicon wafer leaving a predetermined thickness (for example, 5 to 15 μm) from a bonded interface, and subsequently polishing or etching the silicon wafer, thereby removing residual portion to the thinning-stopper layer.

A sixth aspect of the present invention is an epitaxial wafer including: a silicon wafer; and an epitaxial layer formed on a surface of the silicon wafer, wherein an active layer and a thinning-stopper layer in which silicon particles, silicon oxides, and boron ions are mixed are sequentially formed in the surface layer portion of the silicon wafer.

The above-described epitaxial wafer comprises an epitaxial film, an active layer beneath the epitaxial layer, and a thinning-stopper layer beneath the active layer, wherein the thinning-stopper layer is composed of a mixture including silicon particles, silicon oxides, and boron ions.

The above-described epitaxial wafer may further include a gettering layer containing boron between the active layer and the thinning-stopper layer.

In the above-described epitaxial wafer, oxygen ion implantation defects are trapped by boron ions implanted in the formation of the thinning-stopper layer. Therefore, it is possible to reduce the frequency of generation of growth defects (epitaxial defects) of the epitaxial film caused by the presence of the ion implantation defects. Further, during the formation of an epitaxial film accompanied by heating, metallic impurities in the epitaxial film or metallic impurities in the active layer are trapped by boron. Therefore, the above-described epitaxial wafer has an epitaxial film of high quality reduced in defects and metallic impurities.

Further, when a bonded wafer having the above-described epitaxial wafer and a base substrate are thinned during a production process of a semiconductor device, it is possible to perform stopping of polishing or stopping of etching precisely utilizing the thinning-stopper layer.

The above-described epitaxial wafer may be produced by the above-described method of producing an epitaxial wafer according to an aspect of the present invention. For example, the above-described epitaxial wafer may be an epitaxial wafer produced by a process including: forming an ion implanted layer in a surface layer of a silicon wafer by implanting oxygen ions from a surface of the silicon wafer; implanting boron ions in the whole area on the ion implanted layer after forming the ion implanted layer; heat treating the ion implanted layer after implanting boron, thereby forming the thinning-stopper layer and forming the active layer on a surface side of the silicon wafer compared to the thinning-stopper layer; and subsequently forming an epitaxial film on the surface of the silicon wafer.

A seventh aspect of the present invention is an epitaxial wafer according to the above-described sixth aspect, wherein the thinning-stopper layer has been implanted with oxygen ions in a dose of 1×10¹⁴ to 2×10¹⁷ atoms/cm². That is, in this epitaxial wafer, area density of the oxygen included in the thinning-stopper layer may be 1×10¹⁴ to 2×10¹⁷ atoms/cm².

An eighth aspect of the present invention is an epitaxial wafer according to the above-described seventh aspect, wherein the thinning-stopper layer has been implanted with boron ions in a dose of 1×10¹⁵ to 1×10¹⁶ atoms/cm². That is, in this epitaxial wafer, area density of the boron included in the thinning-stopper layer may be 1×10¹⁵ to 1×10¹⁶ atoms/cm².

A ninth aspect of the present invention is an epitaxial wafer according to the above-described seventh or eighth aspect, wherein a portion having a peak concentration of boron in the thinning-stopper layer is at a depth of ±500 Å. of a depth of a portion of peak (highest) oxygen concentration.

In this epitaxial wafer, a depth of the highest boron concentration is within a range of ±500 Å of a depth (for example, a depth from an interface between the silicon wafer and the epitaxial layer) of highest oxide density in the thinning-stopper layer.

An epitaxial wafer according to the above-described aspects has a thinning-stopper layer in the surface layer of the silicon wafer, where silicon particles, silicon oxides, and boron are mixed in the thinning-stopper layer. Accompanied to the formation of the thinning-stopper layer, oxygen ions are implanted to the silicon wafer. In that time, since the oxygen ion implantation defects are trapped by boron, it is possible to reduce a frequency of generation of growth defects of the epitaxial film caused by the presence of the oxygen ion implantation defects.

Further, metallic impurities in the epitaxial film and metallic impurities in the active layer are trapped by boron at the time of forming the epitaxial film accompanied by heating. As a result, it is possible to form an epitaxial film of high quality.

In addition, when a bonded wafer comprising the epitaxial wafer and a base substrate bonded to the epitaxial wafer is subjected to thinning from the back surface side of the silicon wafer, it is possible to perform stopping of polishing and/or stopping of etching precisely utilizing the thinning-stopper layer.

### BRIEF DESCRIPTION OF DRAWINGS

FIG. 1 is a cross-sectional view including a partial enlarged view of an epitaxial wafer according to an embodiment of the present invention.

FIG. 2 is a cross-sectional view showing a process of oxygen ion implantation in a method of producing an epitaxial wafer according to an embodiment of the present invention.

FIG. 3 is a cross-sectional view showing a process of boron ion implantation in a method of producing an epitaxial wafer according to an embodiment of the present invention.

FIG. 4 is a cross-sectional view showing a heat treatment process in a method of producing an epitaxial wafer according to an embodiment of the present invention.

FIG. 5 is a cross-sectional view showing an epitaxial growth process in a method of producing an epitaxial wafer according to an embodiment of the present invention.

FIG. 6 is a cross-sectional view showing a formation process of a device in an epitaxial film of an epitaxial wafer according to an embodiment of the present invention.

FIG. 7 is a cross-sectional view showing a bonding process to bond a support substrate to an epitaxial wafer according to an embodiment of the present invention.

FIG. 8 is a cross sectional view showing a thinning process of a bonded wafer comprising an epitaxial wafer according to an embodiment of the present invention and a support substrate bonded to the epitaxial wafer.

FIG. 9 is a cross sectional view showing a CIS type solid-state imaging device produced using an epitaxial wafer according to an embodiment of the present invention.

### DETAILED DESCRIPTION OF THE INVENTION

In the following, an embodiment of the present invention is explained with reference to the drawings. It should be noted that each of the drawings is a schematic diagram and does not limit a specific size of respective constitutions.

FIG. 1 schematically shows an epitaxial wafer 10 according to an embodiment of the present invention. The epitaxial wafer 10 has a silicon wafer 11, and an epitaxial layer 14 formed on the surface of the silicon wafer 11. An active layer 13, a gettering layer 12A, and a thinning-stopper layer 12 are sequentially stacked in the silicon wafer 11 of this embodiment from the surface (interface between the silicon wafer 11 and the epitaxial layer 14) of the silicon wafer 11. The active layer 13 is substantially composed of silicon. Silicon of the gettering layer 12A includes boron c. Silicon particles a, silicon oxides b, and boron c are mixed in the thinning-stopper layer 12.

For example, the silicon wafer 11 may be produced by performing the below described processes sequentially. In accordance with the CZ method, an ingot of a silicon single crystal may be pulled from a silicon melt contained in a crucible. After that the silicon single crystal ingot is cut to blocks. After grinding a periphery of each block, the block is sliced to a plurality of wafers using a wire saw. Each wafer is subjected to chamfering, lapping, etching, cleaning or the like.

The thus obtained silicon wafer 11 is sequentially subjected to oxygen ion implantation, boron ion implantation, heat treatment, and epitaxial growth.

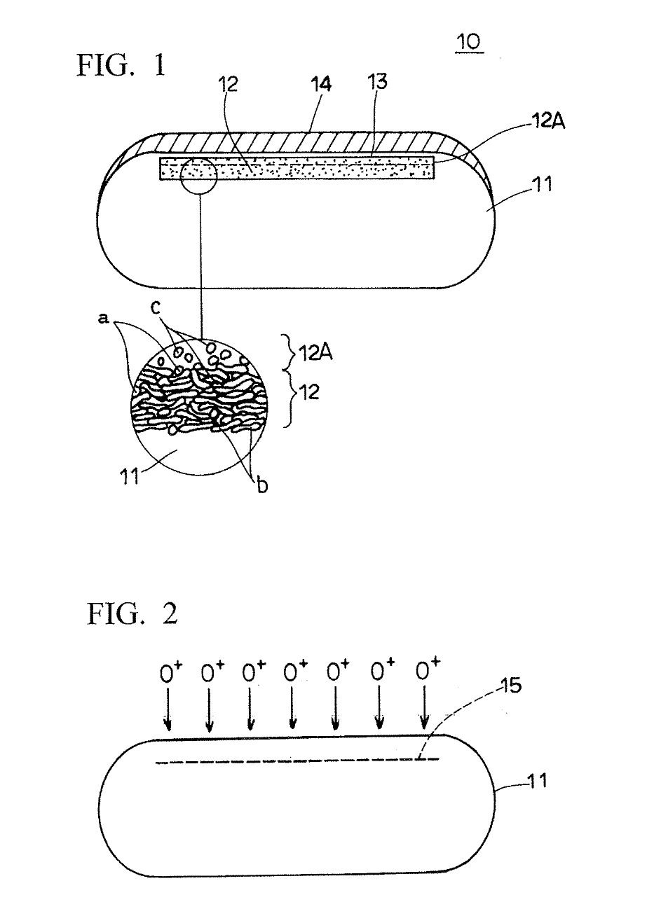

In the oxygen ion implantation shown in FIG. 2, oxygen ions are implanted from a surface of the silicon wafer 11 to substantially whole area of the wafer, thereby forming an oxygen ion implanted layer 15 in the surface layer of the silicon wafer.

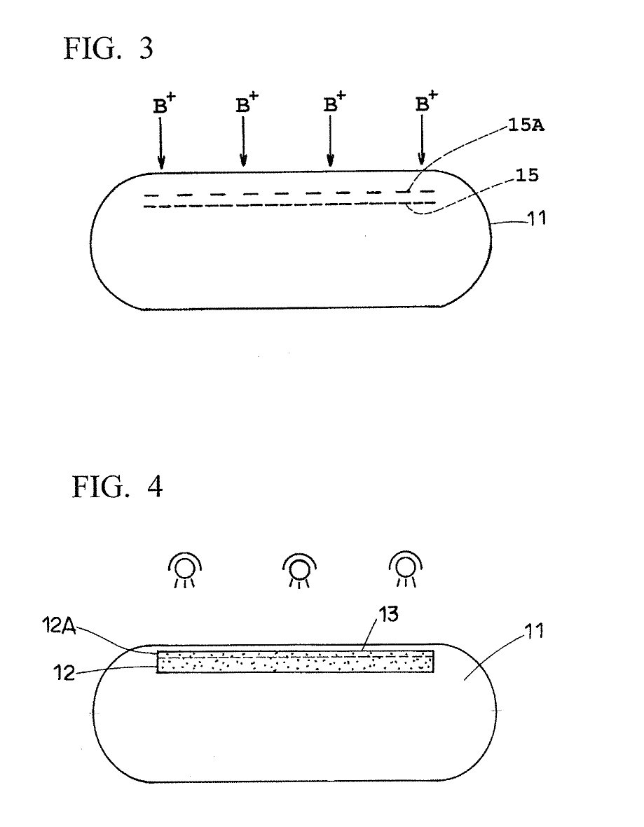

In the boron ion implantation shown in FIG. 3, boron ions are implanted from a surface of the silicon wafer 11 to substantially whole area of the wafer, thereby forming a boron ion implanted layer 15A in the whole area beneath the surface of the wafer and above the oxygen ion implanted layer 15.

In the heat treatment shown by FIG. 4, the oxygen ion implanted layer 15 and the boron ion implanted layer 15A are heat treated directly after the boron ion implantation. As a result, a thinning-stopper layer 12 is formed in the surface layer of the silicon wafer 11. Silicon particles a, silicon oxides b, and boron c are mixed in the thinning-stopper layer 12. In the present embodiment, a gettering layer 12A containing boron c is formed on the surface-side compared to the thinning-stopper layer 12.

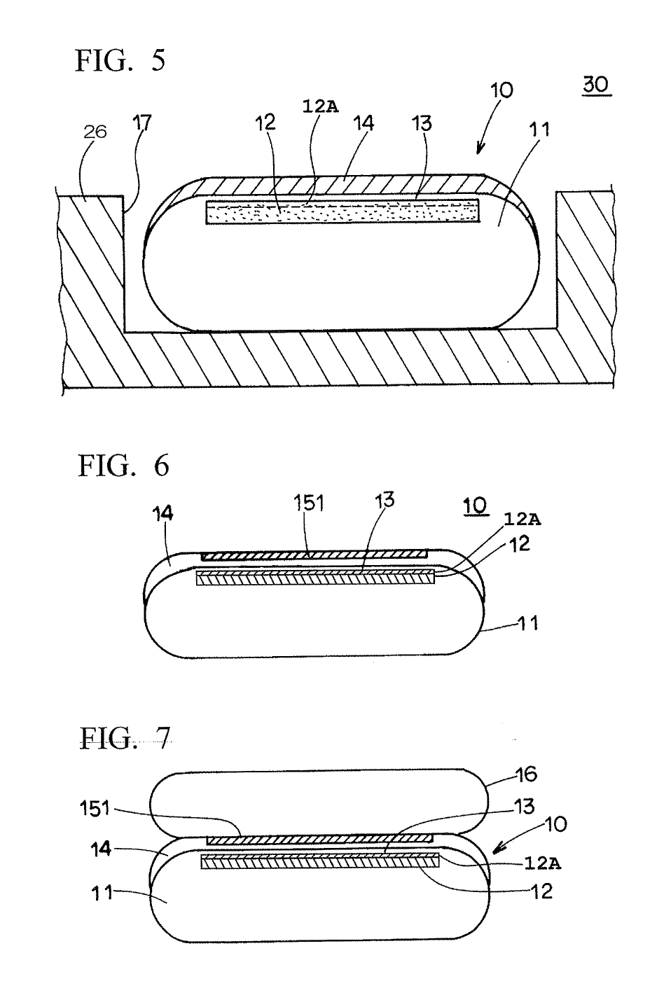

In the epitaxial growth shown by FIG. 5, the silicon wafer 11 is installed in a chamber (epitaxial growth furnace) 30 of the epitaxial growth apparatus, and an epitaxial film 14 is grown on the surface of the silicon wafer 11.

Hereafter, production of an epitaxial wafer according to an embodiment of the present invention is explained more specifically.

### Oxygen Ion Implantation

In the oxygen ion implantation process, silicon wafer 11 is installed in an ion implantation apparatus (FIG. 2). Next, oxygen ions are implanted from the surface of the silicon wafer 11 into the surface layer of the silicon wafer 11 with an energy of 20 to 220 keV while heating the substrate at a temperature of 200 to 600° C. The dose of oxygen ion implantation may be 1.0×10¹⁴ to 2.0×10¹⁷ atoms/cm², preferably 1.0×10¹⁵ to 1.0 ×10¹⁷ atoms/cm².

Preferably, the above-described surface layer is included in a portion at a depth of 0.05 to 0.5 μm from a surface of the silicon wafer. When a depth of the oxygen-ion implanted potion is smaller than 0.05 μm, surface defects of the silicon wafer increase. When the depth of the oxygen-ion implanted potion exceeds 0.5 μm, it is impossible to perform the implantation using a commercially available ion implantation apparatus, causing a requirement for a specific apparatus having high implantation energy.

When the oxygen implantation dose is less than 1.0×10¹⁴ atoms/cm², it is impossible to form a thinning-stopper layer throughout the whole area of the silicon wafer. When the oxygen implantation dose exceeds 2.0×10¹⁷ atoms/cm², a long time is required for the oxygen ion implantation, resulting in a reduction of productivity and an increased cost. A more preferable dose of oxygen ion implantation is 1.0×10¹⁵ to 1.0×10¹⁷ atoms/cm². Within this range, it is possible to form a uniform thinning-stopper layer throughout the whole area of the wafer at relatively low cost.

When the heating temperature of the wafer during the oxygen ion implantation is lower than 200° C., damages due to oxygen ion implantation remain in the surface layer of the silicon wafer. When the heating temperature exceeds 600° C., increasing degassing from the ion implantation apparatus results in deterioration of vacuum degree of the apparatus and unstable operation conditions of the apparatus.

When the implantation energy of oxygen is less than 20 keV, surface defects of the silicon wafer is enlarged. When the implantation energy of oxygen exceeds 220 keV, it is impossible to perform the implantation using a commercially available ion implantation apparatus, causing a requirement for a specific apparatus having high implantation energy.

The implantation of oxygen ions may be performed by a single step, or by a plurality of steps. When the oxygen ion implantation is performed in a plurality of steps, it is possible to implant the oxygen ions with different implantation energy in respective steps. The oxygen ion implantation may be performed in accordance with a method used in a SIMOX process, for example, a low energy method (not more than 100 keV), a low-dose method, or a modified low-dose method.

### Boron Ion Implantation

Next, boron ion implanted layer is formed in a position with a predetermined depth from the surface of the silicon wafer 11 (FIG. 3). The boron ion implantation may be performed using the same apparatus used in the oxygen ion implantation.

While the boron ion implanted layer 15A is formed in a portion shallower than the oxygen ion implanted layer 15 in FIG. 3, it is allowable to implant boron ions such that a peak depth of boron ion implantation is deeper than a peak depth of the oxygen ion implantation. Preferably, the peak depth of the boron ion implantation is controlled to be in the range of ±500 Å of the peak depth of the oxygen ion implantation. When the peak depth of the boron ion implantation is outside the range of ±500 Å of the peak depth of oxygen ion implantation, it is impossible to form a thinning-stopper layer. The preferable peak depth of the boron ion implantation is in the range of ±300 Å of the peak depth of oxygen ion implantation. When the peak depth of the boron ion implantation is controlled in this range, it is possible to form further strong thinning-stopper layer.

Preferably, a dose of boron ion implantation is controlled to be in the range of 1.0×10¹⁵ to 1.0×10¹⁶ atoms/cm². When the dose of boron ion implantation is less than 1.0×10¹⁵ atoms/cm², the thinning-stopper layer cannot exert a sufficient effect as a stopping layer. When the dose of boron ion implantation exceeds 1.0×10¹⁶ atoms/cm², a long time is required for boron ion implantation, resulting in reduction of productivity and an increase of cost. A more preferable dose of boron ion implantation is in the range of 1.0×10¹⁵ to 5.0×10¹⁵ atoms/cm². When the dose of boron ion implantation is controlled to be in this range, it is possible to form a strong thinning-stopper layer at relatively low cost.

### Heat Treatment

Next, the silicon wafer 11 after the boron ion implantation is subjected to heat treatment at a temperature of 900 to 1200° C. for a duration of 0.5 to 4 hours. When the heating temperature is lower than 900° C., it is impossible to form the thinning-stopper layer sufficiently. For a heat treatment at a temperature higher than 1200° C., it is required to use a specific annealing furnace configured to ultra-high temperature treatment. When the duration of heat treatment of the wafer is shorter than 0.5 hours, it is impossible to form a satisfactory thinning-stopper layer. When the duration of heat treatment of the wafer exceeds 4 hours, the productivity of epitaxial wafer is reduced, resulting in high cost. It is preferable to perform the heat treatment in an inert gas atmosphere such as an argon gas atmosphere.

As a result of the heat treatment, a thinning-stopper layer is formed such that silicon oxide b, silicon particles a, and boron c are mixed with predetermined proportions. The silicon oxides b may include oxide precipitates and/or banded oxides made of SiOx (x denotes an atomic ratio of oxygen) which may include SiO₂. The silicon particles b are made as a result of pulverization of silicon in the silicon wafer caused by the oxygen ion implantation.

The thinning-stopper layer 12 is an imperfect silicon oxide film (imperfect buried oxide film) buried in the surface layer (surface vicinity layer) of the silicon wafer. That is, in the whole area of the oxygen ion implanted layer, the silicon oxide film is formed discontinuously (intermittently).

Preferably, a thickness of the thinning-stopper layer is controlled to 0.05 to 0.5 μm. When the thickness of the thinning-stopper layer is less than 0.05 μm, the layer cannot function sufficiently as a layer to detect the termination point of a thinning treatment of a silicon wafer. When a thickness of the thinning-stopper layer exceeds 0.5 μm, a long time is required for the oxygen ion implantation, resulting in reduction of productivity of the epitaxial wafer, and high cost.

In the present embodiment, a gettering layer 12A including boron is formed on the surface-side of the thinning-stopper layer 12 in the silicon wafer 11. An active layer 13 is formed on the gettering layer.

Since the active layer 13 is made of a silicon single crystal, it is possible to grow an epitaxial film 14 constituted of silicon single crystal on the active layer 13.

### Epitaxial Growth

In the epitaxial growth, silicon wafer 11 is arranged in a reaction chamber of the epitaxial growth apparatus, and an epitaxial film 14 is grown on the surface of the silicon wafer 11 (FIG. 5). The thus grown epitaxial film 14 may be a silicon epitaxial film 14.

The epitaxial growth may be performed by a general method, such as vapor phase epitaxial method (VPE), liquid phase epitaxial method (LPE), and solid phase epitaxial method (SPE). A chemical vapor phase deposition method (CVD) is mainly used in the epitaxial growth of silicon based on the consideration of superior crystallinity of the grown layer, high productivity, simple constitution of the apparatus, and facilities in the formation of various device structures.

When a silicon epitaxial film is formed by a chemical vapor deposition method (CVD), silicon-containing source gas and carrier gas are introduced into the reaction furnace and silicon is deposited on a surface of a preliminarily heated silicon wafer, thereby forming an epitaxial film of a predetermined thickness. As a chemical compound containing silicon, it is preferable to use any one selected from SiH₄, SiH₂Cl₂, SiHCl₃, and SiCl₄ because of satisfactory purity, reaction rate, and simple handling. As an epitaxial growth furnace, it is possible to use a high-frequency induction heating furnace or a lamp-heating furnace.

Preferably, thickness of an epitaxial film is 1 to 20 μm. When the thickness of the epitaxial film is less than 1 μm, it is impossible to form a device in the epitaxial film. When a thickness of the epitaxial film exceeds 20 μm, productivity of the epitaxial wafer is reduced, resulting in high cost.

Epitaxial growth temperature, that is, heating temperature of the wafer at the time of epitaxial growth is preferably 1000 to 1200° C. When the temperature is lower than 1000° C., crystallinity of the epitaxial film is deteriorated. When the temperature exceeds 1200° C., slips are likely to occur.

For example, FIG. 5 shows a state in a chamber 30 of a vapor phase epitaxial growth apparatus. A susceptor 26 having a circular shape in plan view is arranged horizontally in the center portion of the chamber 30. Heaters (not shown) are arranged at a position above the chamber and at a position below the chamber. A wafer holding section (wafer housing section) 17 having a recessed shape is formed in a central portion of a surface of the susceptor 26. The wafer holding section 17 holds a silicon wafer 11 such that a front surface and a back surface of the silicon wafer 11 are set horizontally. A pair of gas supply ports (not shown) are disposed to one side of the chamber 30. The gas supply ports flow a predetermined carrier gas (for example, H₂ gas) and a predetermined source gas (for example, SiHCl₃ gas) into an upper space within the chamber 30 in a direction parallel to a surface of the silicon wafer 11. A gas exhaust port (not shown) is disposed to the other side of the chamber 30 to exhaust the carrier gas and the source gas.

At the time of epitaxial growth, firstly, a silicon wafer 11 is placed on the wafer holding section 17 of the susceptor 26 such that a front and a back surface of the wafer are arranged horizontally. Next, carrier gas and source gas are introduced into the reaction chamber via respective gas supply ports. By flowing source gas on a silicon wafer 11 heated at a high temperature, an epitaxial film 14 of silicon single crystal having a predetermined thickness is formed on a surface of the silicon wafer 11. Thus, an epitaxial wafer 10 is produced.

The above-described heat treatment and the epitaxial growth may be performed using the same reaction furnace. For example, a silicon wafer may be subjected to a heat treatment at a temperature of 900 to 1200° C. for a duration of 0.5 to 4 hours while flowing inert gas in the chamber, and a single crystalline silicon film may be epitaxially grown on the surface of the silicon wafer after the heat treatment by controlling the heating temperature at 1000 to 1200° C., and changing the inflow-gas to a source gas containing Si and carrier gas.

### Formation of a Solid-State Imaging Device

Next, a formation process of a solid-state imaging device using an epitaxial wafer 10 of the above-described embodiment is explained.

A device (solid-state imaging device) 151 is formed by a predetermined photo-processing of a surface of the epitaxial film 14 (FIG. 6). After that, a base substrate 16 made of a semiconductor material (for example, single crystalline silicon) is bonded on the surface of the epitaxial film 14 (FIG. 7). The base-substrate may have an oxide film formed on the surface.

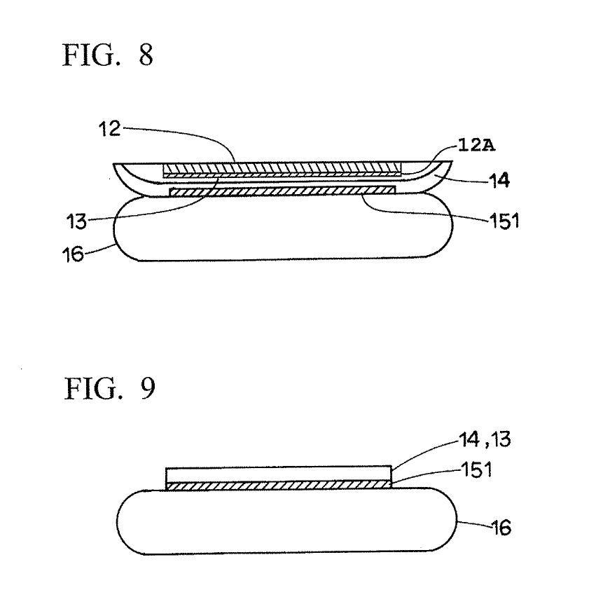

Then, the silicon wafer 11 of the epitaxial wafer 10 is subjected to thinning from its back-side by grinding and polishing (FIG. 8). At that time, the thinning-stopper layer 12 functions as an oxide layer for selective removal of the silicon wafer 11. That is, the thinning-stopper layer 12 functions as stopper of thinning when the thinning of the silicon wafer 11 reaches the thinning-stopper layer 12. When the surface polishing of the silicon wafer 11 reaches the silicon oxides b, the polishing pad slips by being contact with the thinning-stopper layer 12. At this time, polishing torque of the polishing apparatus is deteriorated. A timing of stopping the polishing may be detected by detecting the slip of the polishing pad.

Grinding may be performed using a resinoid grinder. For example, it is possible to use a grinder of #800 (having a particle size of abrasive grains of 15 to 25 μm).

For example, the silicon wafer may be ground to a position (thickness) of 5 to 15 μm from the bonding interface, and subsequently subjected to polishing.

As an alternative to the grinding and polishing of the epitaxial wafer 10, thinning of the wafer may be performed by etching. In that case, the thinning-stopper layer 12 functions as etching-stopper member. The etching may be performed by wet etching or by dry etching. In the case of wet etching by using an HF/HNO₃/CH₃COOH solution or alkaline-base solution (for example, KOH), when the etching reaches from the silicon wafer 11 to the thinning-stopper layer 12, the etching rate is reduced in the thinning-stopper layer 12 due to the difference of material properties between silicon and silicon oxide b. However, it is required to monitor the changing thickness since the etch-stopping function of the thinning-stopper layer is not perfect in the case of wet-etching.

In the case of dry etching, it is possible to use a method of exposing the material (wafer) in the reaction gas (reactive etching gas) or a reactive ion etching using an ionized/radicalized gas (plasma). XeF₂ may be used in the reactive gas etching. SF₆, CF₄, or CHF₃ may be generally used in the reactive ion etching. As a method of generating plasma, it is possible to apply a capacitive-coupled method, inductive-coupled method, ECR-RIE method or the like. Since the exposed film is not a perfect silicon oxide film but an imperfect oxide film, it is possible to remove the film by polishing. The thinning may be performed by converting to a perfect oxide by oxidation heat treatment at a temperature of 600 to 10000° C. for about 1 to 30 minutes, and removing the oxide by HF solution.

Thus, a CIS type solid state imaging device having the device element embedded in the back side of the epitaxial film 14 (between the epitaxial film 14 and base substrate 16) is obtained (FIG. 9).

In an epitaxial wafer 10 of the above-described constitution, dose of oxygen implantation was controlled to be lower than that of the buried oxide film of a conventional epitaxial SIMOX wafer, and the oxygen ion implanted layer was heat treated at a temperature lower than that of conventional high temperature annealing. Because of a lower dose of oxygen implantation compared to the conventional SIMOX wafer and because of the omission of high temperature annealing, it is possible to produce an epitaxial wafer at a lower cost compared to the conventional epitaxial SIMOX wafer.

The surface layer of the silicon wafer 11 includes a thinning-stopper layer 12 having a mixture of silicon particles a, silicon oxides b, and boron c, and a gettering layer 12A including boron c. By this constitution, it is possible to trap the oxygen ion implantation defects (defects generated by the oxygen ion implantation to the surface layer of the silicon wafer) by gettering sites of boron c during the implantation of boron into the surface layer of the silicon wafer 11 that accompanies thinning-stopper layer. As a result, it is possible to reduce a frequency of generation of growth defects of the epitaxial film 14 caused by the oxygen ion implantation defects. Further, the thinning-stopper layer 12 containing boron c and the gettering layer 12A containing boron c constitute gettering sites of metallic impurities included in the active layer 13 and the epitaxial film 14. Therefore, it is possible to prevent the metallic contamination in the silicon wafer 11, and the device 151.

### EXAMPLES

### Example 1

An epitaxial wafer 10 was produced in accordance with the method of the above-described embodiment, and a solid state imaging device 151 was produced using the epitaxial wafer.

Firstly, a silicon wafer 11 was prepared. The silicon wafer 11 had a thickness of 775 μm, a diameter of 300 mm, and axial orientation of the surface of <100>.

The silicon wafer 11 was installed on an ion implantation apparatus. While heating the silicon wafer 11 at a temperature of 400° C., oxygen ions were implanted from the surface of the silicon wafer 11 with an ion implantation energy of 200 keV, where a dose of implantation was 1.5×10¹⁷ atoms/cm² and a peak depth of the ion implantation was 0.44 μm. Thus, an oxygen ion implanted layer 15 comprising lower grade oxides such as SiO, and Si₂O₃ was formed in a depth of 0.44 μm from a surface of the silicon wafer 11 (FIG. 2).

Next, using the same apparatus used in the oxygen ion implantation, boron ions were implanted to the silicon wafer (FIG. 3). The silicon wafer 11 was not heated. Boron ions were implanted from the surface of the silicon wafer 11 with an ion implantation energy of 120 keV, where a dose of implantation was 5.0×10¹⁵ atoms/cm² and a peak depth of the ion implantation was 0.40 μm which was 400 Å shallower than a peak depth of oxygen ion implantation.

By the above-described process, a boron ion implanted layer 15A was formed in a depth of 0.40 μm from a surface of the silicon wafer 11.

Next, the silicon wafer 11 after the boron ion implantation was installed in a batch type heat treatment furnace and was subjected to a heat treatment at a temperature of 1200° C. for 30 minutes under an atmosphere of 100% of argon gas. By this treatment, a thinning-stopper layer 12 with a thickness of about 0.1 μm was formed, where silicon oxides b, silicon particles a, and boron c (boron atoms, boron ions) were mixed with a predetermined proportion in the thinning-stopper layer 12. The silicon oxides b were composed of banded oxides or grains of oxide precipitates having a composition of SiOₓ (x denotes a ratio of oxygen) including SiO₂. The silicon particles were formed as a result of oxygen implantation which pulverized silicon in the silicon wafer 11 into particles. In the same time, a gettering layer 12A mainly composed of silicon and boron and having a thickness of 0.05 μm and an active layer 13 having a thickness of 0.4 μm were sequentially formed in the silicon wafer 11 on the surface-side of the thinning-stopper layer 12.

After the heat treatment, the silicon wafer 11 was disposed in a reaction chamber of a single wafer type vapor-phase epitaxial growth apparatus, and an epitaxial film 14 was grown on the surface of the silicon wafer 11 by vapor-phase epitaxial method (FIG. 5).

At the time of epitaxial growth, firstly, a silicon wafer 11 was placed in the wafer holding portion 17 of a susceptor 26 within the chamber 30 such that a front and back surface of the wafer were arranged horizontally. Next, carrier gas (H₂ gas) and source gas (SiHCl₃ gas) were introduced into the chamber via the corresponding gas supply ports. By flowing the source gas on a surface of the silicon wafer heated at 1150° C., an epitaxial film 14 of silicon single crystal with a thickness of 5 μm was grown on the surface of the silicon wafer 11.

In the above-described formation of an epitaxial wafer 10, the dose of oxygen implantation of 1.5×10¹⁷ atoms/cm² was smaller than that (for example, 25×10¹⁷ atoms/cm²) in the case of forming a conventional epitaxial SIMOX wafer, and the oxygen ion implanted layer 15 was heat treated at 1200° C. which was lower than a temperature (for example, 1350° C.) of conventional high temperature annealing. Since the dose of oxygen implantation was smaller than the conventional SIMOX wafer and high temperature annealing was avoided, an epitaxial wafer was produced at a cost lower than a production cost of the epitaxial SIMOX wafer.

Next, a solid-state imaging device 151 was formed by subjecting a surface of the epitaxial film 14 of the thus obtained epitaxial wafer 10 to a predetermined photo-process (FIG. 6). After that, a base substrate 16 composed of single crystalline silicon with a diameter of 300 mm and a thickness of 775 μm was bonded to the surface of the epitaxial film 14 (FIG. 7).

Next, silicon wafer 11 of the epitaxial wafer was subjected to thinning from its back side by grinding and polishing (FIG. 8).

During the polishing, the thinning-stopper layer 12 behaved as an oxide layer which contributed to selective removal of the silicon wafer 11. That is, the thinning-stopper layer 12 behaved as a stopper of polishing at a time when the thinning of the silicon wafer 11 was reached the thinning-stopper layer 12. When the surface polishing of the silicon wafer 11 reached the silicon oxides b, a polishing pad slipped being contact with the thinning-stopper layer 12. As a result, polishing torque of the polishing apparatus was reduced. Silicon wafer 11 could be selectively removed by detecting the timing of stopping polishing based on detection of the reduction of the torque.

### Example 2

Frequency of generation of growth defects during the formation of epitaxial film, success/non-success of polish-stopping and etch-stopping utilizing the thinning-stopper layer, and an amount of Cu contamination on a surface of an epitaxial film at a time 30 days after the fabrication of the epitaxial wafer were evaluated for epitaxial wafers produced by the method of the present invention and epitaxial wafers produced by the conventional method.

### Experiment 1

Fifty p-type (10 Ω·cm) silicon wafers each having a diameter of 300 mm were prepared. Oxygen ions were implanted from a surface of each silicon wafer into the surface layer (surface vicinity layer) with an implantation energy of 200 keV, and a dose (dose of implantation) of 5.0×10¹⁶ atoms/cm² while heating the silicon wafer at a temperature of 350° C.

Next, boron ions were implanted from a surface of each silicon wafer after the oxygen ion implantation into the surface layer of the silicon wafer with an implantation energy of 120 keV, and a dose of 5.0×10¹⁵ atoms/cm², where the silicon wafer was not heated.

After that, each silicon wafer was subjected to a heat treatment at 1200° C. for 30 minutes in a batch type heat treatment furnace under an argon gas atmosphere.

Next, an epitaxial film with a thickness of 0.5 μm and a resistivity of 10 Ω·cm was grown on the surface of each silicon wafer using a single wafer type epitaxial growth apparatus. Conditions of the epitaxial growth were similar to those used in Example 1.

### Comparative Experiment 1

Fifty p-type (10 Ω·cm) silicon wafers each having a diameter of 300 mm were prepared. Oxygen ions were implanted from a surface of each silicon wafer into the surface layer (surface vicinity layer) with an implantation energy of 200 keV, and a dose of 5.0×10¹⁶ atoms/cm² while heating the silicon wafer at a temperature of 350° C.

Next, oxygen ions were implanted for a second time from a surface of each silicon wafer after the oxygen ion implantation into the surface layer of the silicon wafer with an implantation energy of 200 keV, and a dose of 5.0×10¹⁵ atoms/cm², where the silicon wafer was not heated.

After that, each silicon wafer was subjected to a heat treatment at 1200° C. for 30 minutes in a batch type heat treatment furnace under an argon gas atmosphere.

Next, an epitaxial film with a thickness of 0.5 μm and a resistivity of 10 Ω·cm was grown on the surface of each silicon wafer using a single wafer type epitaxial growth apparatus. The conditions of the epitaxial growth were similar to those used in Example 1.

### Experiment 2

Fifty p-type (10 Ω·cm) silicon wafers each having a diameter of 300 mm were prepared. Oxygen ions were implanted from a surface of each silicon wafer into the surface layer (surface vicinity layer) with an implantation energy of 200 keV, and a dose of 5.0×10¹⁶ atoms/cm² while heating the silicon wafer at a temperature of 350° C. Next, boron ions were implanted from a surface of each silicon wafer after the oxygen ion implantation into the surface layer of the silicon wafer with an implantation energy of 120 keV, and a dose of 5.0×10¹⁵ atoms/cm², where the silicon wafer was not heated.

After that, each silicon wafer was subjected to a heat treatment at 1200° C. for 30 minutes in a batch type heat treatment furnace under an argon gas atmosphere.

Next, an epitaxial film with a thickness of 3.0 μm and a resistivity of 10 Ω·cm was grown on the surface of each silicon wafer using a single wafer type epitaxial growth apparatus. Conditions of the epitaxial growth were similar to those used in Example 1.

### Comparative Experiment 2

Fifty p-type (10 Ω·cm) silicon wafers each having a diameter of 300 mm were prepared. Oxygen ions were implanted from a surface of each silicon wafer into the surface layer (surface vicinity layer) with an implantation energy of 200 keV, and a dose of 5.0×10¹⁶ atoms/cm² while heating the silicon wafer at a temperature of 350° C.

Next, oxygen ions were implanted for a second time from a surface of each silicon wafer after the oxygen ion implantation into the surface layer of the silicon wafer with an implantation energy of 200 keV, and a dose of 5.0×10¹⁵ atoms/cm², where the silicon wafer was not heated.

After that, each silicon wafer was subjected to a heat treatment at 1200° C. for 30 minutes in a batch type heat treatment furnace under an argon gas atmosphere.

Next, an epitaxial film with a thickness of 3.0 μm and a resistivity of 10 Ω·cm was grown on the surface of each silicon wafer using a single wafer type epitaxial growth apparatus. Conditions of the epitaxial growth were similar to those used in Example 1.

Frequency of generation of growth defects during the formation of epitaxial film, success/non-success of polish-stopping and etch-stopping utilizing the thinning-stopper layer, and an amount of Cu contamination on a surface of an active layer after a contaminative polishing were evaluated for each of the thus produced epitaxial wafers. The results are shown in Table 1.

TABLE 1

| Thickness of | | | Epitaxial | Success/non-success | Success/non-success | Cu concentration | |
|---|---|---|---|---|---|---|---|
| epitaxial film | | | defects | of polish-stopping | of etch-stopping | on surface | |
| 1 | 0.5 μm | Experiment 1 | 5 to 10/wf | Succeeded | Succeeded | <1.0 × 10¹⁰ | atoms/cm² |
| | | Comparative | 500 to 1500/wf | Succeeded | Partially failed | 1.0 × 10¹¹ | atoms/cm² |
| | | Experiment 1 | | | | | |
| 2 | 3.0 μm | Experiment 2 | 10 to 20/wf | Succeeded | Succeeded | <1.0 × 10¹⁰ | atoms/cm² |
| | | Comparative | 600 to 2000/wf | Succeeded | Partially failed | 1.0 × 10¹¹ | atoms/cm² |
| | | Experiment 2 | | | | | |

The results of evaluation are described below in detail. Each fifty samples of Experiment 1, Experiment 2, Comparative Experiment 1, and Comparative Experiment 2 were subjected to a measurement of numbers of defects larger than 65 nm using a surface defect inspection apparatus (SP-2, made by KLA Tencor Coporation). Number of defects per a silicon wafer was apparently smaller in Experiment 1 and Experiment 2 than in Comparative Experiment 1 and Comparative Experiment 2.

Each 25 samples after the defect measurement were each bonded with a base substrate having an oxide film with a thickness of 1500 Å. The conditions of bonding were similar to those described in Example 1. After that, each silicon wafer was subjected to grinding and polishing so as to examine the function of polish-stopping. The evaluation was performed by visual inspection, where presence or absence of insufficient polishing and/or excessive polishing was examined. Polish-stopping was successively performed in all of Example 1, Example 2, Comparative Example 1, and Comparative Example 2. That is, each wafer had a thinning-stopper layer that functioned as a polish-stopper layer.

Each 25 samples after the defect measurement were each bonded with a base substrate having an oxide film with a thickness of 1500 Å. After that, each silicon wafer was subjected to grinding and polishing, and was further subjected to etching so as to examine the function of etch-stopping. The evaluation was performed by visual inspection, where presence or absence of insufficient etching and/or excessive etching was examined. In the peripheral portion of each wafer of Comparative Experiment 1 and Comparative Experiment 2, etching proceeded beyond the thinning-stopper layer towards the active layer and the epitaxial layer. On the other hand, etch-stopping at the thinning-stopper layer was confirmed in the whole wafer surface in Example 1 and in Example 2.

Each five samples were selected from the samples after the polish stopping and etch-stopping. The stopped surface of each sample was polished using a polishing fluid containing Cu of 30 ppb. After the polishing, the thinning-stopper layer was removed from each sample, and Cu concentration on the surface of the active layer integrated with the epitaxial film was examined. As a result, Cu of 1.0×10¹¹ atoms/cm² was detected in Comparative Experiment 1, and Comparative Experiment 2. On the other hand, in Experiment 1 and Experiment 2, the concentration of Cu was 1.0×10¹¹ atoms/cm² or less.

While preferred embodiments of the invention have been described and illustrated above, it should be understood that these are exemplary of the invention and are not to be considered as limiting. Additions, omissions, substitutions, and other modifications can be made without departing from the scope of the present invention. Accordingly, the invention is not to be considered as being limited by the foregoing description, and is only limited by the scope of the appended claims.

What is claimed is:

1. A method of producing an epitaxial wafer, comprising:
implanting oxygen ions from a surface of a silicon wafer, thereby forming an ion implanted layer in a surface layer of the silicon wafer;
after forming the ion implanted layer, implanting boron ions from the surface of the silicon wafer to the whole area on the ion implanted layer;
performing heat treatment of the silicon wafer after implanting boron ions, thereby forming a thinning-stopper layer including a mixture of silicon particles, silicon oxides, and boron, and forming an active layer in the silicon wafer on the surface side of the thinning-stopper layer; and
forming an epitaxial layer on the surface of the silicon wafer after the heat treatment.

2. A method of producing an epitaxial wafer according to claim 1, wherein a dose of the oxygen ion implantation is 1.0×10¹⁴ to 2.0×10¹⁷ atoms/cm².

3. A method of producing an epitaxial wafer according to claim 1, wherein a dose of the boron ion implantation is 1.0×10¹⁵ to 1.0×10¹⁶ atoms/cm².

4. A method of producing an epitaxial wafer according to claim 2, wherein a dose of the boron ion implantation is 1.0×10¹⁵ to 1.0×10¹⁶ atoms/cm².

5. A method of producing an epitaxial wafer according to claim 1, wherein a peak depth of the boron ion implantation is ±500 Å of a peak depth of the oxygen ion implantation.

6. A method of producing an epitaxial wafer according to claim 2, wherein a peak depth of the boron ion implantation is ±500 Å of a peak depth of the oxygen ion implantation.

7. A method of producing an epitaxial wafer according to claim 3, wherein a peak depth of the boron ion implantation is ±500 Å of a peak depth of the oxygen ion implantation.

8. A method of producing an epitaxial wafer according to claim 4, wherein a peak depth of the boron ion implantation is ±500 Å of a peak depth of the oxygen ion implantation.

9. An epitaxial wafer comprising a silicon wafer and an epitaxial film formed on a surface of the epitaxial wafer, wherein
an active layer and a thinning-stopper layer are sequentially formed from a surface of the silicon wafer in a surface layer of the silicon wafer, where silicon particles, silicon oxides, and boron are mixed in the thinning-stopper layer.

10. An epitaxial wafer according to claim 9, wherein an oxygen ions in a dose of 1.0×10¹⁴ to 2.0×10¹⁷ atoms/cm² are implanted in the thinning-stopper layer.

11. An epitaxial wafer according to claim 9, wherein boron ions in a dose of 1.0×10¹⁵ to 1.0×10¹⁶ atoms/cm² are implanted in the thinning-stopper layer.

12. An epitaxial wafer according to claim 10, wherein boron ions in a dose of 1.0×10¹⁵ to 1.0×10¹⁶ atoms/cm² are implanted in the thinning-stopper layer.

13. An epitaxial wafer according to claim 9, wherein a depth of a portion of peak boron concentration is in a range of ±500 Å of a depth of a portion of peak oxygen concentration in the thinning-stopper layer.

14. An epitaxial wafer according to claim 10, wherein a depth of a portion of peak boron concentration is in a range of ±500 Å of a depth of a portion of peak oxygen concentration in the thinning-stopper layer.

15. An epitaxial wafer according to claim 11, wherein a depth of a portion of peak boron concentration is in a range of ±500 Å of a depth of a portion of peak oxygen concentration in the thinning-stopper layer.

16. An epitaxial wafer according to claim 12, wherein a depth of a portion of peak boron concentration is in a range of ±500 Å of a depth of a portion of peak oxygen concentration in the thinning-stopper layer.
